(19) United States
(12) Patent Application Publication
(10) Pub. No.: US 2025/0297892 A1
(43) Pub. Date: Sep. 25, 2025

(54) OPTICAL SENSOR, RECEIVER DEVICE, TRANSCEIVER DEVICE, COMMUNICATION SYSTEM, TERMINAL DEVICE, AND OPTICAL SYSTEM

(71) Applicant: TDK CORPORATION, Tokyo (JP)

(72) Inventors: Yusho HIRATA, Tokyo (JP); Tomohito MIZUNO, Tokyo (JP); Tetsuya SHIBATA, Tokyo (JP); Hideaki FUKUZAWA, Tokyo (JP)

(73) Assignee: TDK CORPORATION, Tokyo (JP)

(21) Appl. No.: 19/079,187

(22) Filed: Mar. 13, 2025

(30) Foreign Application Priority Data
Mar. 19, 2024 (JP) 2024-043401

(51) Int. Cl. G01J 1/44

(52) U.S. Cl. CPC G01J 1/44

(57) ABSTRACT

An optical sensor, a receiver device, a transceiver device, a communication system, a terminal device, and an optical system that can curb interfacial reflection are provided. The optical sensor includes a photosensitive layer that generating a voltage in a case where the photosensitive layer is irradiated with light, a first electrode, a second electrode, and a metal layer. The photosensitive layer is located between the first electrode and the second electrode. The metal layer is located between the first electrode and the photosensitive layer. The metal layer includes one selected from a group consisting of Ti, Ta, Cr, Mo, W, and Pt.

### BACKGROUND OF THE INVENTION

### Field of the Invention

The present invention relates to an optical sensor, a receiver device, a transceiver device, a communication system, a terminal device, and an optical system.

### Description of Related Art

Photoelectric converters have been used for various purposes.

For example, Patent Document 1 discloses a receiver device that receives an optical signal using a photodiode. A photodiode is, for example, a pn junction diode using a pn junction of semiconductor and converts light to an electrical signal.

For example, Patent Document 2 discloses a novel optical device using a magnetic element. A magnetic state of a magnetic element changes and a resistance value thereof changes when the magnetic element is irradiated with light.

### PATENT DOCUMENTS

[Patent Document 1] Japanese Unexamined Patent Application, First Publication No. 2001-292107

[Patent Document 2] Japanese Unexamined Patent Application, First Publication No. 2023-90284

### SUMMARY OF THE INVENTION

An optical sensor converts light to an electrical signal. When incident light is reflected before reaching a photosensitive layer of the optical sensor, sufficient light cannot be input to the photosensitive layer.

The present invention was made in consideration of the aforementioned circumstances, and an objective thereof is to provide an optical sensor, a receiver device, a transceiver device, a communication system, a terminal device, and an optical system that can curb interfacial reflection.

In order to achieve the aforementioned object, the following means are provided.

An optical sensor according to an embodiment includes a photosensitive layer that generating a voltage when the photosensitive layer is irradiated with light, a first electrode, a second electrode, and a metal layer. The photosensitive layer is located between the first electrode and the second electrode. The metal layer is located between the first electrode and the photosensitive layer. The metal layer includes one selected from a group consisting of Ti, Ta, Cr, Mo, W, and Pt in a case where the photosensitive layer is irradiated with light of a wavelength equal to or greater than 400 nm and equal to or less than 800 nm. The metal layer includes one selected from a group consisting of Ti, Cr, Mo, W, and Pt in a case where the photosensitive layer is irradiated with light of a wavelength equal to or greater than 400 nm and equal to or less than 1400 nm. The metal layer includes one selected from a group consisting of Ti, Cr, W, and Pt in a case where the photosensitive layer is irradiated with light of a wavelength equal to or greater than 400 nm and equal to or less than 1500 nm.

With the optical sensor according to the aspect, interfacial reflection decreases.

### BRIEF DESCRIPTION OF THE DRAWINGS

FIG. 1 is a sectional view of an optical sensor according to a first embodiment.

FIG. 2 is a diagram illustrating measurement results of reflectance at an interface between a first electrode and a metal layer in the optical sensor according to the first embodiment.

FIG. 3 is a diagram illustrating a relationship between a thermal conductivity of a metal layer and a light-receiving sensitivity of a photosensitive layer in the optical sensor according to the first embodiment.

FIG. 4 is a diagram illustrating a relationship between a thickness of a metal layer and a light-receiving sensitivity of a photosensitive layer in the optical sensor according to the first embodiment.

FIG. 5 is a diagram illustrating an operation example of the optical sensor according to the first embodiment.

FIG. 6 is a diagram illustrating an operation example of the optical sensor according to the first embodiment.

FIG. 7 is a sectional view of the optical sensor according to a first modified example.

FIG. 8 is a diagram schematically illustrating an optical unit according to a first application example.

FIG. 9 is a conceptual diagram of an optical system using the optical unit according to the first application example.

FIG. 10 is a diagram schematically illustrating a transceiver device according to a second application example.

FIG. 11 is a conceptual diagram illustrating an example of a communication system.

FIG. 12 is a conceptual diagram illustrating another example of the communication system.

### DETAILED DESCRIPTION OF THE INVENTION

Hereinafter, an embodiment will be described in detail with appropriate reference to the accompanying drawings. In the drawings used in the following description, featured parts may be conveniently enlarged for the purpose of easy understanding of features, and dimensions, ratios, and the like of constituents may be different from actual ones. Materials, dimensions, and the like exemplified in the following description are merely examples, and the present invention is not limited thereto and can be appropriately modified within ranges in which the advantageous effects of the present invention can be achieved.

Directions are defined. One in-plane direction of a plane in which layers extend is defined as an X direction, and a direction perpendicular to the X direction in the plane is defined as a Y direction. A stacking direction perpendicular to the layers is defined as a Z direction. In the following description, the +Z direction may be referred to as “upward,” and the −Z direction may be referred to as “downward.” The +Z direction is a direction directed from a second electrode 22 to a first electrode 21. Upward and downward do not necessarily match a direction in which a gravitational force is applied.

### First Embodiment

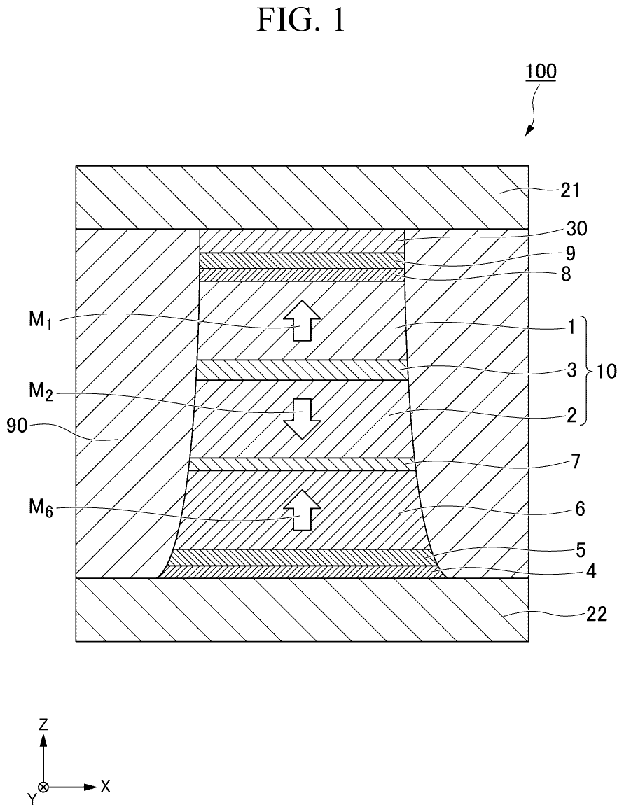

FIG. 1 is a sectional view of an optical sensor 100 according to a first embodiment. In FIG. 1, a direction of a magnetization in an initial state of a ferromagnetic substance is indicated by an arrow.

The optical sensor 100 includes a photosensitive layer 10, a first electrode 21, a second electrode 22, and a metal layer 30. The photosensitive layer 10 is provided between the first electrode 21 and the second electrode 22. The metal layer 30 is provided between the first electrode 21 and the photosensitive layer 10.

The optical sensor 100 may further include a buffer layer 4, a seed layer 5, a third ferromagnetic layer 6, a magnetic coupling layer 7, a perpendicular magnetization inducing layer 8, a cap layer 9, and an insulating layer 90. The buffer layer 4, the seed layer 5, the third ferromagnetic layer 6, and the magnetic coupling layer 7 are located 20 between the photosensitive layer 10 and the second electrode 22, and the perpendicular magnetization inducing layer 8 and the cap layer 9 are located between the photosensitive layer 10 and the metal layer 30. The insulating layer 90 is located between the first electrode 21 and the second electrode 22 and covers a laminate including the photosensitive layer 10.

The optical sensor 100 converts a state or a change in state of applied light to an electrical signal. Light in this specification is not limited to visible light and includes infrared light of longer wavelengths than visible light and ultraviolet light of shorter wavelengths than visible light. The wavelength of the visible light is, for example, equal to or greater than 380 nm and less than 800 nm. The wavelength of the infrared light is, for example, equal to or greater than 800 nm and less than 1 mm. The wavelength of the ultraviolet light is, for example, equal to or greater than 200 nm and less than 380 nm. For example, the optical sensor 100 (the photosensitive layer 10) is irradiated with light of a wavelength equal to or greater than 400 nm and equal to or less than 1500 nm. According to the purpose of the optical sensor 100, the photosensitive layer 10 may be irradiated with light of a wavelength equal to or greater than 400 nm and equal to or less than 800 nm.

The photosensitive layer 10 generates a voltage when it is irradiated with light. When the state of light applied thereto changes, a resistance value in the Z direction of the photosensitive layer 10 changes with the change in the state of light. When the state of light applied to the photosensitive layer 10 changes, an output voltage from the optical sensor 100 changes with the change in the state of light. The photosensitive layer 10 includes, for example, a first ferromagnetic layer 1, a second ferromagnetic layer 2, and a spacer layer 3. The spacer layer 3 is located between the first ferromagnetic layer 1 and the second ferromagnetic layer 2. The photosensitive layer 10 may include other layers.

The photosensitive layer 10 is a magnetic element including a ferromagnetic substance. For example, when the spacer layer 3 is formed of an insulator, the photosensitive layer 10 includes a magnetic tunnel junction (MTJ) which is constituted by the first ferromagnetic layer 1, the spacer layer 3, and the second ferromagnetic layer 2. This element is referred to as an MTJ element. In this case, the photosensitive layer 10 can exhibit a tunnel magnetoresistance (TMR) effect. When the spacer layer 3 is formed of a metal, the photosensitive layer 10 can exhibit a giant magnetoresistance (GMR) effect. This element is referred to as a GMR element. The photosensitive layer 10 is referred to as different names such as an MTJ element and a GMR element according to the material of the spacer layer 3 and is also collectively referred to as a magnetoresistance effect element. A resistance value in the Z direction (a resistance value when a current flows in the Z direction) of the photosensitive layer 10 changes according to a relative change of a magnetization M₁ state of the first ferromagnetic layer 1 and a magnetization M₂ state of the second ferromagnetic layer 2.

The first ferromagnetic layer 1 is a light sensing layer in which a magnetization state changes when light is externally applied thereto. The first ferromagnetic layer 1 is also referred to as a magnetization free layer. The magnetization free layer is a layer including a magnetic substance in which a magnetization state changes when predetermined energy is externally applied thereto. The predetermined energy from the outside includes, for example, light which is applied from the outside, a current which flows in the Z direction of the photosensitive layer 10, and an external magnetic field. The magnetization M₁ state of the first ferromagnetic layer 1 changes according to an intensity of light applied to the first ferromagnetic layer 1 (light applied to the photosensitive layer 10).

The first ferromagnetic layer 1 includes a ferromagnetic substance. The first ferromagnetic layer 1 includes, for example, at least one of magnetic elements such as Co, Fe, and Ni. The first ferromagnetic layer 1 may include elements such as B, Mg, Hf, and Gd in addition to the aforementioned magnetic elements. The first ferromagnetic layer 1 may be formed of, for example, an alloy including a magnetic element and a nonmagnetic element. The first ferromagnetic layer 1 may include a plurality of layers. The first ferromagnetic layer 1 is, for example, a CoFeB alloy layer, a laminate in which a CoFeB alloy layer is interposed between Fe layers, or a laminate in which a CoFeB alloy layer is interposed between CoFe layers. In general, “ferromagnetism” includes “ferrimagnetism.” The first ferromagnetic layer 1 may exhibit ferrimagnetism. On the other hand, the first ferromagnetic layer 1 may exhibit ferromagnetism other than ferrimagnetism. For example, the CoFeB alloy exhibits ferromagnetism other than ferrimagnetism.

The first ferromagnetic layer 1 may be an in-plane magnetized film having an easy magnetization axis in an in-plane direction (some directions in the xy plane) or may be a perpendicularly magnetized film including an easy magnetization axis in a plane-perpendicular direction (the Z direction).

The thickness of the first ferromagnetic layer 1 is, for example, equal to or greater than 1 nm and equal to or less than 5 nm. For example, it is preferable that the thickness of the first ferromagnetic layer 1 be equal to or greater than 1 nm and equal to or less than 2 nm. When the first ferromagnetic layer 1 is a perpendicularly magnetized film and the thickness of the first ferromagnetic layer 1 is small, a perpendicular magnetic anisotropy application effect from layers located on and below the first ferromagnetic layer 1 is strengthened, and the perpendicular magnetic anisotropy of the first ferromagnetic layer 1 is enhanced. That is, when the perpendicular magnetic anisotropy of the first ferromagnetic layer 1 is high, a force for returning a magnetization M₁ in the Z direction is increased. On the other hand, when the thickness of the first ferromagnetic layer 1 is large, the perpendicular magnetic anisotropy application effect from layers located on and below the first ferromagnetic layer 1 is weakened, and the perpendicular magnetic anisotropy of the first ferromagnetic layer 1 is weakened.

When the thickness of the first ferromagnetic layer 1 decreases, a volume serving as a ferromagnetic substance decreases. When the thickness of the first ferromagnetic layer 1 increases, the volume serving as a ferromagnetic substance increases. A magnetization M₁ reactivity of the first ferromagnetic layer 1 when external energy is applied thereto is inversely proportional to a product (KuV) of the magnetic anisotropy (Ku) and the volume of the first ferromagnetic layer 1. That is, when the product of the magnetic anisotropy and the volume of the first ferromagnetic layer 1 decreases, the reactivity to light increases. From this viewpoint, it is preferable to appropriately design the magnetic anisotropy of the first ferromagnetic layer 1 and to decrease the volume of the first ferromagnetic layer 1 in order to increase the reactivity to light.

When the thickness of the first ferromagnetic layer 1 is larger than 2 nm, for example, an insertion layer formed of Mo or W may be provided in the first ferromagnetic layer 1. That is, a laminate in which a ferromagnetic layer, an insertion layer, and a ferromagnetic layer are sequentially stacked in the Z direction may be used as the first ferromagnetic layer 1. The perpendicular magnetic anisotropy of the first ferromagnetic layer 1 as a whole is increased by interface magnetic anisotropy at an interface between the insertion layer and the ferromagnetic layer. The thickness of the insertion layer ranges, for example, from 0.1 nm to 1.0 nm.

The second ferromagnetic layer 2 is a magnetization fixed layer. The magnetization fixed layer is a layer formed of a magnetic substance in which a state of a magnetization M₂ is less likely to change than the magnetization free layer when predetermined energy is externally applied thereto. For example, a magnetization direction of the magnetization fixed layer is less likely to change than that of the magnetization free layer when predetermined energy is externally applied thereto. For example, a magnetization magnitude of the magnetization fixed layer is less likely to change than that of the magnetization free layer when predetermined energy is externally applied thereto. For example, a coercive force of the second ferromagnetic layer 2 is larger than a coercive force of the first ferromagnetic layer 1. The second ferromagnetic layer 2 includes, for example, an easy magnetization axis of the same direction as the first ferromagnetic layer 1. The second ferromagnetic layer 2 may be an in-plane magnetized film or a perpendicularly magnetized film.

For example, the material of the second ferromagnetic layer 2 is the same as the first ferromagnetic layer 1. The second ferromagnetic layer 2 may be, for example, a multi-layered layer in which Co with a thickness of 0.4 nm to 1.0 nm and Pt with a thickness of 0.4 nm to 1.0 nm are alternately stacked by several turns. The second ferromagnetic layer 2 may be, for example, a laminate in which Co with a thickness of 0.4 nm to 1.0 nm, Mo with a thickness of 0.1 nm to 0.5 nm, a CoFeB alloy with a thickness of 0.3 nm to 1.0 nm, and Fe with a thickness of 0.3 nm to 1.0 nm are alternately stacked.

The magnetization M₂ of the second ferromagnetic layer 2 may be fixed, for example, by magnetic coupling to a magnetization M₆ of the third ferromagnetic layer 6. In this case, the second ferromagnetic layer 2, the magnetic coupling layer 7, and the third ferromagnetic layer 6 may be collectively referred to as a magnetization fixed layer. Details of the magnetic coupling layer 7 and the third ferromagnetic layer 6 will be described later.

The spacer layer 3 is a layer which is disposed between the first ferromagnetic layer 1 and the second ferromagnetic layer 2. The spacer layer 3 is constituted by a layer formed of a conductor, an insulator, or a semiconductor or a layer including a conductive spot formed of a conductor in an insulator. The spacer layer 3 is, for example, a nonmagnetic layer. The thickness of the spacer layer 3 can be adjusted according to alignment directions of the magnetization of the first ferromagnetic layer 1 and the magnetization of the second ferromagnetic layer 2 in an initial state which will be described later.

When the spacer layer 3 is formed of an insulating material, a material including aluminum oxide, magnesium oxide, titanium oxide, or silicon oxide can be used as the material of the spacer layer 3. This insulating material may include an element such as Al, B, Si, or Mg or a magnetic element such as Co, Fe, or Ni. By adjusting the thickness of the spacer layer 3 such that a high TME effect is exhibited between the first ferromagnetic layer 1 and the second ferromagnetic layer 2, a high magnetoresistance change rate is obtained. In order to efficiently use the TMR effect, the thickness of the spacer layer 3 may be set to about 0.5 nm to 5.0 nm or about 1.0 nm to 2.5 nm.

When the spacer layer 3 is formed of a nonmagnetic conductive material, a conductive material such as Cu, Ag, Au, or Ru can be used. In order to efficiently use the GMR effect, the thickness of the spacer layer 3 may be set to about 0.5 nm to 5.0 nm or about 2.0 nm to 3.0 nm.

When the spacer layer 3 is formed of a nonmagnetic semiconductor material, a material such as zinc oxide, indium oxide, tin oxide, germanium oxide, gallium oxide, or ITO can be used. In this case, the thickness of the spacer layer 3 may be set to 1.0 nm to 4.0 nm.

When a layer including a conductive spot formed of a conductor in a nonmagnetic insulator is used as the spacer layer 3, a structure in which a conductive spot formed of a nonmagnetic conductor such as Cu, Au, or Al is included in a nonmagnetic insulator formed of aluminum oxide or magnesium oxide may be employed. The conductor may include a magnetic element such as Co, Fe, or Ni. In this case, the thickness of the spacer layer 3 may be set to 1.0 nm to 2.5 nm. The conductive spot is, for example, a columnar member with a diameter of 1 nm to 5 nm when seen in a direction perpendicular to a film plane.

The third ferromagnetic layer 6 is magnetically coupled to, for example, the second ferromagnetic layer 2. Magnetic coupling is, for example, antiferromagnetic coupling and is caused by an RKKY interaction. The material of the third ferromagnetic layer 6 is, for example, the same as the first ferromagnetic layer 1.

The magnetic coupling layer 7 is located between the second ferromagnetic layer 2 and the third ferromagnetic layer 6. The magnetic coupling layer 7 is formed of, for example, Ru or Ir.

The buffer layer 4 is a layer for buffering lattice mismatch between different crystals. The buffer layer 4 is, for example, a metal including at least one type of element selected from a group consisting of Ta, Ti, Zr, and Cr or a nitride including at least one type of element selected from a group consisting of Ta, Ti, Zr, and Cu. More specifically, the buffer layer 4 is formed of, for example, Ta (simple substance), an NiCr alloy, tantalum nitride (TaN), or copper nitride (CuN). The thickness of the buffer layer 4 is, for example, equal to or greater than 1 nm and equal to or less than 5 nm. The buffer layer 4 is, for example, amorphous. For example, the buffer layer 4 is located between the seed layer 5 and the second electrode 22 and is in contact with the second electrode 22. The buffer layer 4 curbs an influence of a crystal structure of the second electrode 22 on a crystal structure of the photosensitive layer 10.

The seed layer 5 increases crystallizability of a layer which is stacked on the seed layer 5. For example, the seed layer 5 is located between the buffer layer 4 and the third ferromagnetic layer 6 and is located on the buffer layer 4. The seed layer 5 is formed of, for example, Pt, Ru, Zr, or NiFeCr. The thickness of the seed layer 5 is, for example, equal to or greater than 1 nm and equal to or less than 5 nm.

The cap layer 9 is located between the first ferromagnetic layer 1 and the first electrode 21. The cap layer 9 may include a perpendicular magnetization inducing layer 8 which is stacked on the first ferromagnetic layer 1 and which is in contact with the first ferromagnetic layer 1. The cap layer 9 prevents damage on an underlying layer in the course of processing and enhances crystallizability at the time of annealing. The thickness of the cap layer 9 is, for example equal to or less than 10 nm such that sufficient light is applied to the first ferromagnetic layer 1.

The perpendicular magnetization inducing layer 8 induces perpendicular magnetic anisotropy of the first ferromagnetic layer 1. The perpendicular magnetization inducing layer 8 is formed of, for example, magnesium oxide, W, Ta, or Mo. When the perpendicular magnetization inducing layer 8 is formed of magnesium oxide, it is preferable that magnesium oxide be deficient in oxygen in order to enhance conductivity. The thickness of the perpendicular magnetization inducing layer 8 is, for example, equal to or greater than 0.5 nm and equal to or less than 5.0 nm.

The insulating layer 90 is formed of, for example, oxides, nitrides, or oxynitrides of Si, Al, or Mg. The insulating layer 90 is formed of, for example, silicon oxide (SiOₓ), silicon nitride (SiNₓ), silicon carbide (SiC), chromium nitride, silicon carbo-nitride (SiCN), silicon oxynitride (SiON), aluminum oxide (Al₂O₃), or zirconium oxide (ZrOₓ).

The first electrode 21 is disposed on a side on which incident light is incident on the optical sensor 100. Incident light is applied from the first electrode 21 side to the photosensitive layer 10. The first electrode 21 is formed of a conductive material. The first electrode 21 is, for example, a transparent electrode having transmissivity to light in a use wavelength band. For example, it is preferable that the first electrode 21 transmit 80% or more of light in the use wavelength band. The use wavelength band of light is, for example, equal to or greater than 300 nm and equal to or less than 2 μm, preferably equal to or greater than 400 nm and equal to or less than 1500 nm, and more preferably equal to or greater than 400 nm and equal to or less than 800 nm. The first electrode 21 is formed of, for example, oxides such as indium tin oxide (ITO), indium zinc oxide (IZO), zinc oxide (ZnO), or indium gallium zinc oxide (IGZO). The first electrode 21 may have a structure in which a plurality of columnar metals are provided in a transparent electrode material of oxides. The first electrode 21 may include an antireflection film on an irradiation surface which is irradiated with light.

The second electrode 22 is formed of a conductive material. The second electrode 22 is formed of, for example, metal such as Cu, Al, or Au. Ta or Ti may be stacked on or under the metal. A stacked film of Cu and Ta, a stacked film of Ta, Cu, and Ti, or a stacked film of Ta, Cu, and TaN may be used as the second electrode 22. TiN or TaN may be used as the second electrode 22.

The second electrode 22 may be formed of, for example, a metal including at least one element selected from a group constituting of ruthenium, molybdenum, and tungsten. The second electrode 22 may be a single-layered film of one of ruthenium, molybdenum, and tungsten or may be a stacked film including a layer of at least one of ruthenium, molybdenum, and tungsten. Ruthenium, molybdenum, and tungsten have high melting points (equal to or higher than 2000° C.) and high thermal resistance. The second electrode 22 including these elements is not likely to deteriorate even when heat treatment for crystalizing a laminate the photosensitive layer 10 and heat treatment in the semiconductor process are performed thereon.

The second electrode 22 reflects a part of incident light which is incident from the first electrode 21 side at an interface with a layer in contact with the second electrode 22 (an interface between the buffer layer 4 and the second electrode 22 and an interface between the insulating layer 90 and the second electrode 22). Ruthenium, molybdenum, and tungsten have a high light reflectance at the interfaces and a high reflectance of light in a wavelength range equal to or greater than 400 nm and equal to or less than 1500 nm at the interfaces. Reflected light reflected by the second electrode 22 is applied to the photosensitive layer 10. Since the second electrode 22 is formed of a predetermined material (a metal including at least one element selected from the group consisting of ruthenium, molybdenum, and tungsten), more incident light is reflected than when the second electrode 2 is formed of a material other than the predetermined material. Accordingly, an amount of light applied to the photosensitive layer 10 in the optical sensor 100 is large.

The metal layer 30 is provided between the photosensitive layer 10 and the first electrode 21. The metal layer 30 is provided, for example, between the cap layer 9 and the first electrode 21.

The metal layer 30 includes one selected from a group consisting of Ti, Ta, Cr, Mo, W, and Pt when the photosensitive layer 10 is irradiated with light of a wavelength equal to or greater than 400 nm and equal to or less than 800 nm. The metal layer 30 includes one selected from a group consisting of Ti, Cr, Mo, W, and Pt when the photosensitive layer 10 is irradiated with light of a wavelength equal to or greater than 400 nm and equal to or less than 1400 nm. The metal layer 30 includes one selected from a group consisting of Ti, Cr, W, and Pt when the photosensitive layer 10 is irradiated with light of a wavelength equal to or greater than 400 nm and equal to or less than 1500 nm.

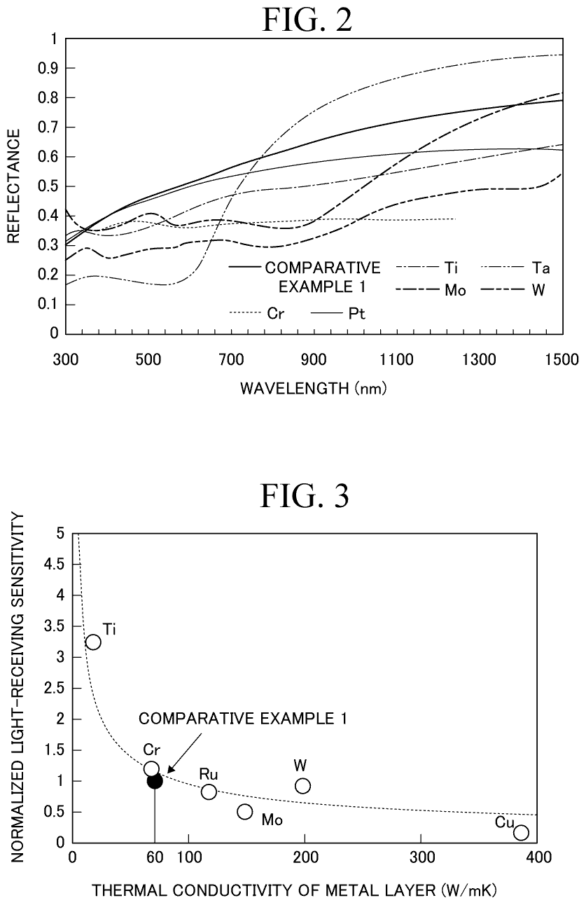

FIG. 2 is a diagram illustrating measurement results of a reflectance at an interface between the first electrode 21 and an underlying layer in the optical sensor according to the first embodiment. Comparative Example 1 represents a measurement result of a reflectance at an interface between the first electrode 21 and the photosensitive layer 10 when the metal layer 30 is not provided between the first electrode 21 and the photosensitive layer 10. The other examples are examples in which one of Ti, Ta, Cr, Mo, W, and Pt is used as the metal layer 30. The photosensitive layer 10 mainly includes Co.

When the photosensitive layer 10 is irradiated with light of a wavelength equal to or greater than 400 nm and equal to or less than 800 nm as illustrated in FIG. 2, it is possible to reduce reflection at the interface by providing the metal layer 30 including one selected from a group consisting of Ti, Ta, Cr, Mo, W, and Pt between the first electrode 21 and the photosensitive layer 10. When the photosensitive layer 10 is irradiated with light of a wavelength equal to or greater than 400 nm and equal to or less than 1400 nm, it is possible to reduce reflection at the interface by providing the metal layer 30 including one selected from a group consisting of Ti, Cr, Mo, W, and Pt between the first electrode 21 and the photosensitive layer 10. When the photosensitive layer 10 is irradiated with light of a wavelength equal to or greater than 400 nm and equal to or less than 1500 nm, it is possible to reduce reflection at the interface by providing the metal layer 30 including one selected from a group consisting of Ti, Cr, W, and Pt between the first electrode 21 and the photosensitive layer 10. When reflection at the interface is reduced, an amount of light applied to the photosensitive layer 10 increases, and light sensibility of the optical sensor 100 increases.

When the first electrode 21 is formed of ITO, IZO, ZnO, IGZO, it is preferable that the metal layer 30 include one selected from the group consisting of Ti, Ta, Cr, Mo, W, and Pt. When this configuration is employed, complex refractive indices of the first electrode 21 and the metal layer 30 can be set to close values, and it is possible to particularly curb reflection between the first electrode 21 and the metal layer 30.

It is preferable that the metal layer 30 include one selected from a group consisting of Ru and Ti when the cap layer 9 is formed of Ru and include one selected from the group consisting of Ta, Cr, Mo, W, and Pt when the cap layer 9 is formed of Ta. When the cap layer 9 and the metal layer 30 satisfy these conditions, it is possible to curb reflection between the cap layer 9 and the metal layer 30.

It is preferable that the thermal conductivity of the metal layer 30 be equal to or less than 60 W/mK. FIG. 3 is a diagram illustrating a relationship between the thermal conductivity of the metal layer 30 and a light-receiving sensitivity of the photosensitive layer 10 in the optical sensor 100 according to the first embodiment. The horizontal axis in FIG. 3 represents the thermal conductivity of the metal layer 30, and the vertical axis in FIG. 3 represents the light-receiving sensitivity in the examples standardized with the light-receiving sensitivity of the photosensitive layer 10 in Comparative Example 1. Comparative Example 1 indicates the light-receiving sensitivity of the photosensitive layer 10 when the metal layer 30 is not provided between the first electrode 21 and the photosensitive layer 10. In the other examples, one of Ti, Cr, Mo, W, Ru, and Cu is used as the metal layer 30. The light-receiving sensitivity is a light-receiving sensitivity when sin-wave laser light with a wavelength of 850 nm, a peak power of 4.8 mW, and 1 GHz is applied. The thickness of the metal layer is set to 200 Å.

As illustrated in FIG. 3, it can be seen that the light-receiving sensitivity of the photosensitive layer 10 increases when the thermal conductivity of the metal layer 30 decreases. This is thought because the metal layer 30 serves as a heat bath and reduces heat diffusion from the photosensitive layer 10. When the temperature of the photosensitive layer 10 increases, the magnetization M₁ of the first ferromagnetic layer 1 moves more easily and the sensitivity of the optical sensor 100 to light increases. It is preferable that the metal layer 30 be formed of Ti or Cr.

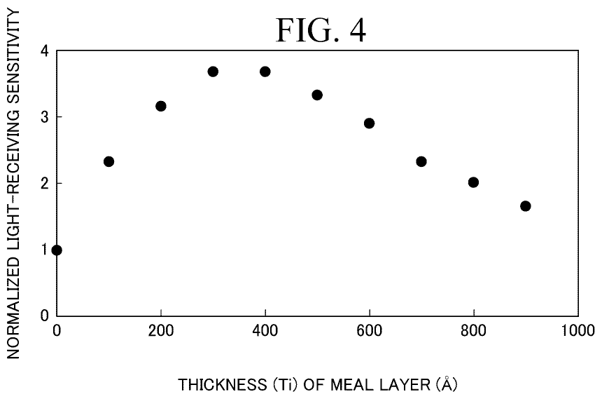

FIG. 4 is a diagram illustrating a relationship between the thickness of the metal layer 30 and the light-receiving sensitivity of the photosensitive layer 10 in the optical sensor 100 according to the first embodiment. FIG. 4 indicates a light-receiving sensitivity when sin-wave laser light with a wavelength of 850 nm, a peak power of 4.8 mW, and 1 GHz is applied, where the thickness of the metal layer 30 formed of Ti is changed.

As illustrated in FIG. 4, the thickness of the metal layer 30 is preferably equal to or greater than 100 Å and equal to or less than 1000 Å, more preferably equal to or greater than 200 Å and equal to or less than 600 Å, and still more preferably equal to or greater than 300 Å and equal to or less than 500 Å. When the thickness of the metal layer 30 is too large, it is considered that heat diffuses from the metal layer 30 to the nearby insulating layer 90 and an amount of heat propagating from the metal layer 30 to the photosensitive layer 10 decreases.

The optical sensor 100 is manufactured through a stacking step, an annealing step, and a processing step for each layer. First, the buffer layer 4, the seed layer 5, the third ferromagnetic layer 6, the magnetic coupling layer 7, the second ferromagnetic layer 2, the spacer layer 3, the first ferromagnetic layer 1, the perpendicular magnetization inducing layer 8, the cap layer 9, and the metal layer 30 are sequentially stacked on the second electrode 22. The layers are formed, for example, by sputtering.

Subsequently, the stacked film is annealed. The annealing temperature is, for example, equal to or higher than 250° C. and equal to or lower than 400° C. Thereafter, the stacked film is processed into a laminate with a columnar shape through photolithography and etching. The laminate may be a circular pillar or a polygonal pillar. For example, a shortest width of the laminate when seen in the Z direction is equal to or greater than 10 nm and equal to or less than 1000 nm.

Subsequently, the insulating layer 90 is formed to cover the side surfaces of the laminate. The insulating layer 90 may be stacked a plurality of times. Subsequently, the top surface of the metal layer 30 is exposed from the insulating layer 90 through chemical mechanical polishing, and the first electrode 21 is formed on the metal layer 30. Through these steps, the optical sensor 100 is obtained.

Operations of the optical sensor 100 will be described below. An output voltage from the optical sensor 100 changes with a change in intensity of light applied to the photosensitive layer 10. The output voltage from the optical sensor 100 changes with a change in resistance value in the Z direction of the optical sensor 100.

When the intensity of light applied to the photosensitive layer 10 of the optical sensor 100 changes from a first intensity to a second intensity, the resistance value in the Z direction of the optical sensor 100 changes. The first intensity may be an intensity when the intensity of light applied to the photosensitive layer 10 is zero. When the resistance value in the Z direction of the optical sensor 100 changes, the output voltage from the optical sensor 100 changes.

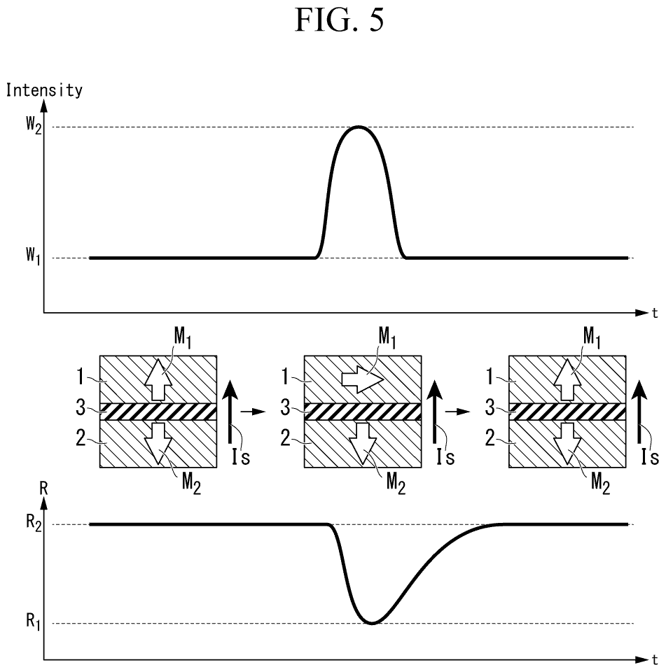

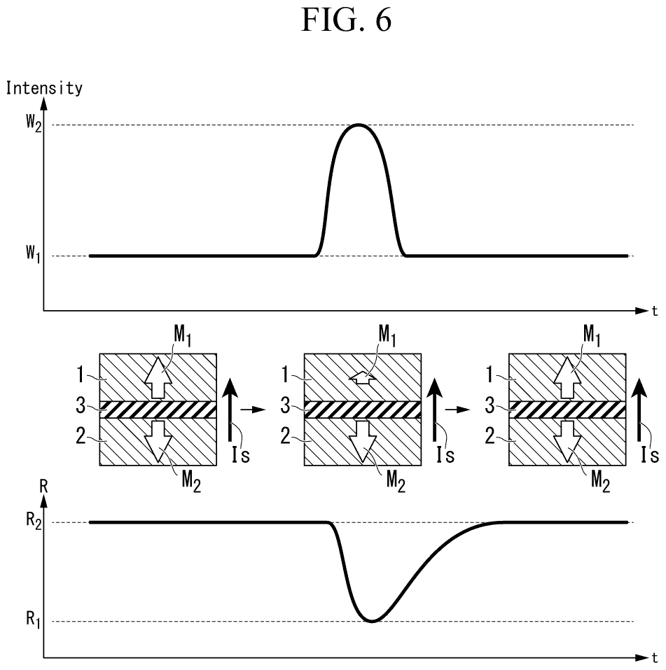

FIGS. 5 and 6 are diagrams illustrating an example of operations of the optical sensor 100 according to the first embodiment. FIG. 5 is a diagram illustrating a first mechanism of the operation example, and FIG. 6 is a diagram illustrating a second mechanism of the operation example. In the upper graphs of FIGS. 5 and 6, the vertical axis represents an intensity of light applied to the first ferromagnetic layer 1, and the horizontal axis represents time. In the lower graphs of FIGS. 5 and 6, the vertical axis represents a resistance value in the Z direction of the optical sensor 100, and the horizontal axis represents time.

First, in a state (hereinafter referred to as an initial state) in which light with a first intensity W₁ is applied to the first ferromagnetic layer 1, the magnetization M₁ of the first ferromagnetic layer 1 and the magnetization M₂ of the second ferromagnetic layer 2 are anti-parallel to each other, and the resistance value in the Z direction of the optical sensor 100 indicates a second resistance value R₂. Here, a state in which the intensity of light applied to the first ferromagnetic layer 1 is zero may be defined as a state in which light with the first intensity W₁ is applied.

By allowing a sensing current Is to flow in the Z direction of the optical sensor 100, a voltage is generated across terminals in the Z direction of the optical sensor 100. The output voltage from the optical sensor 100 is generated between the first electrode 21 and the second electrode 22.

In the example illustrated in FIG. 5, it is preferable that the sensing current Is flow from the second ferromagnetic layer 2 to the first ferromagnetic layer 1. By allowing the sensing current Is to flow in this direction, a spin transfer torque in a direction opposite to the magnetization M₂ of the second ferromagnetic layer 2 acts on the magnetization M₁ of the first ferromagnetic layer 1, and the magnetization M₁ and the magnetization M₂ in the initial state are likely to be antiparallel to each other.

Subsequently, the intensity of light applied to the first ferromagnetic layer 1 changes from the first intensity W₁ to the second intensity W₂. For example, when a light pulse is applied to the photosensitive layer 10, the intensity of light applied to the first ferromagnetic layer 1 changes from the first intensity W₁ to the second intensity W₂. Light with the second intensity W₂ has a larger intensity than light with the first intensity W₁.

The second intensity W₂ is larger than the first intensity W₁, and the magnetization M₁ of the first ferromagnetic layer 1 changes from the initial state. The state of the magnetization M₁ of the first ferromagnetic layer 1 in a state in which light is not applied to the first ferromagnetic layer 1 and the state of the magnetization M₁ of the first ferromagnetic layer 1 in a state in which light with the second intensity W₂ is applied thereto are different from each other. The state of the magnetization M₁ includes, for example, a tilt angle with respect to the Z direction and a magnitude.

For example, when the intensity of light applied to the first ferromagnetic layer 1 changes from the first intensity W₁ to the second intensity W₂ as illustrated in FIG. 5, the magnetization M₁ is tilted with respect to the Z direction. For example, when the intensity of light applied to the first ferromagnetic layer 1 changes from the first intensity W₁ to the second intensity W₂ as illustrated in FIG. 6, the magnitude of the magnetization M₁ decreases. For example, when the magnetization M₁ of the first ferromagnetic layer 1 is tilted with respect to the Z direction according to the intensity of the applied light, the tilt angle is, for example, greater than 0° and less than 90°.

When the magnetization M₁ of the first ferromagnetic layer 1 changes from the initial state with application of a light pulse to the photosensitive layer 10, the resistance value in the Z direction of the optical sensor 100 indicates the first resistance value R₁, and the output voltage from the optical sensor 100 changes from a first value to a second value. As a result, the output from the optical sensor 100 changes. The first resistance value R₁ is less than the second resistance value R₂. The second value is less than the first value. The first resistance value R₁ is a value between a resistance value (the second resistance value R₂) when the magnetization M₁ and the magnetization M₂ are antiparallel and a resistance value when the magnetization M₁ and the magnetization M₂ are parallel.

In the example illustrated in FIG. 5, a spin transfer torque in a direction which is opposite to the magnetization M₂ of the second ferromagnetic layer 2 acts on the magnetization M₁ of the first ferromagnetic layer 1. Accordingly, the magnetization M₁ is going to return to the state in which it is antiparallel to the magnetization M₂, and the magnetization M₁ returns to the state in which it is antiparallel to the magnetization M₂ when the intensity of light applied to the first ferromagnetic layer 1 changes from the second intensity to the first intensity. In the example illustrated in FIG. 6, when the intensity of light applied to the first ferromagnetic layer 1 returns to the first intensity W₁, the magnitude of the magnetization M₁ of the first ferromagnetic layer 1 returns to the original magnitude, and the optical sensor 100 returns to the initial state. In any case, the resistance value in the Z direction of the optical sensor 100 returns to the second resistance value R₂. That is, when the intensity of light applied to the first ferromagnetic layer 1 changes from the second intensity W₂ to the first intensity W₁, the resistance value in the Z direction of the optical sensor 100 changes from the first resistance value R₁ to the second resistance value R₂.

The output voltage from the optical sensor 100 changes with a change of the intensity of light applied to the photosensitive layer 10, and the change of the intensity of the applied light can be converted to a change of the output voltage from the optical sensor 100. That is, the optical sensor 100 can convert light to an electrical signal. For example, a signal when the output voltage from the optical sensor 100 is equal to or greater than a threshold value is defined as a first signal (for example, “1”), and a signal when the output voltage is less than the threshold value is defined as a second signal (for example, “0”).

An example in which the magnetization M₁ and the magnetization M₂ in the initial state are antiparallel has been described above, but the magnetization M₁ and the magnetization M₂ in the initial state may be parallel. In this case, the resistance value in the Z direction of the optical sensor 100 increases as the state of the magnetization M₁ changes (for example, as a change in angle from the initial state of the magnetization M₁ increases). When the initial state is a state in which the magnetization M₁ and the magnetization M₂ are parallel, it is preferable that the sensing current Is flow from the first ferromagnetic layer 1 to the second ferromagnetic layer 2. By allowing the sensing current Is to flow in this direction, a spin transfer torque which has the same direction as the magnetization M₂ of the second ferromagnetic layer 2 acts on the magnetization M₁ of the first ferromagnetic layer 1, and the magnetization M₁ and the magnetization M₂ in the initial state are parallel.

An example in which light applied to the photosensitive layer 10 has two levels of the first intensity and the second intensity has been described above, but the intensity of light applied to the photosensitive layer 10 may change at more levels or in an analog manner. In this case, the output voltage from the optical sensor 100 changes at the more levels or in an analog manner.

The optical sensor 100 according to the first embodiment can convert light to an electrical signal by converting light applied to the photosensitive layer 10 to an output voltage from the optical sensor 100. Since the optical sensor 100 according to the first embodiment includes the metal layer 30 between the first electrode 21 and the photosensitive layer 10, it is possible to reduce interfacial reflection and to enhance light sensibility.

An example of the present invention has been described above in conjunction with the first embodiment, and the present invention is not limited to that embodiment.

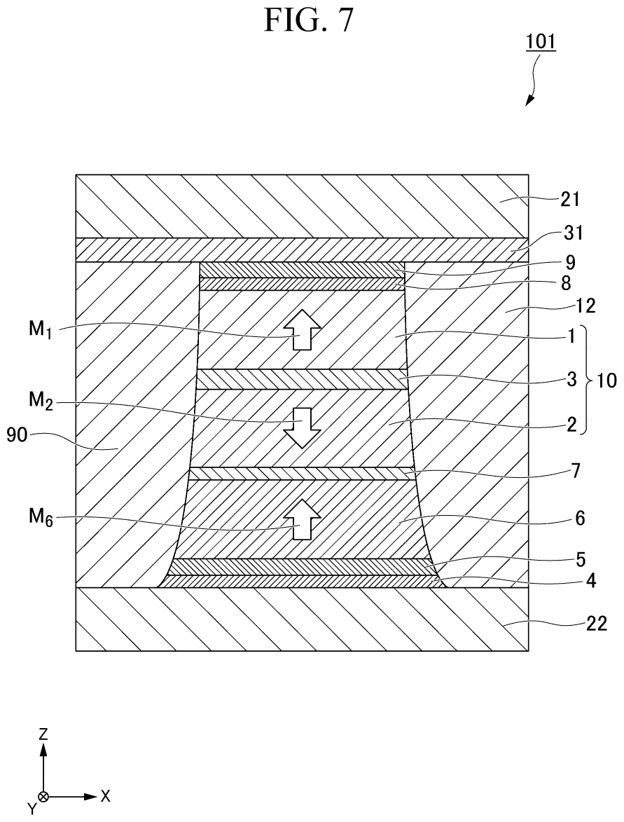

For example, FIG. 7 is a sectional view of an optical sensor 101 according to a first modified example. The optical sensor 101 illustrated in FIG. 7 is different from the optical sensor 100 in that the shape of a metal layer 31 is different from that of the metal layer 30. The metal layer 31 extends outward from the photosensitive layer 10 when seen in the Z direction. With the optical sensor 101 according to the first modified example, it is possible to achieve the same effects as the optical sensor 100.

The optical sensor 100 according to the aforementioned embodiment and the modified example can be used for various purposes.

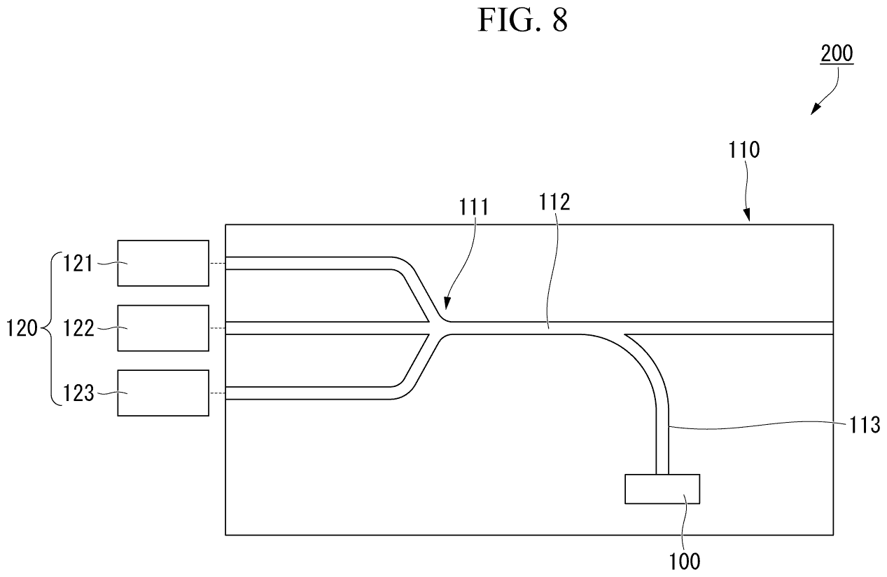

FIG. 8 is a diagram schematically illustrating an optical unit 200 according to a first application example. The optical unit 200 illustrated in FIG. 8 includes a waveguide unit 110 and a light source 120. The waveguide unit 110 includes the aforementioned optical sensor 100 and a waveguide 111. The waveguide 111 includes an output waveguide 112 and a monitoring waveguide 113. The output waveguide 112 is a waveguide for outputting light from the light source 120 to the outside. The monitoring waveguide 113 is a waveguide for divisionally outputting a part of light propagating in the output waveguide 112 to the optical sensor 100. The monitoring waveguide 113 guides light to the optical sensor 100.

The light source 120 is, for example, a laser light source. The light source 120 includes, for example, a red laser 121, a green laser 122, and a blue laser 123. Light output from the light source 120 propagates in the output waveguide 112 and is output to the outside. A part of light output from the light source 120 propagates in the monitoring waveguide 113 and reaches the optical sensor 100.

The optical unit 200 outputs laser light to the outside while monitoring the output from the light source 120 using the optical sensor 100. The optical unit 200 can adjust white balance of light output from the output waveguide 112 to the outside by adjusting the intensity of light output from the lasers.

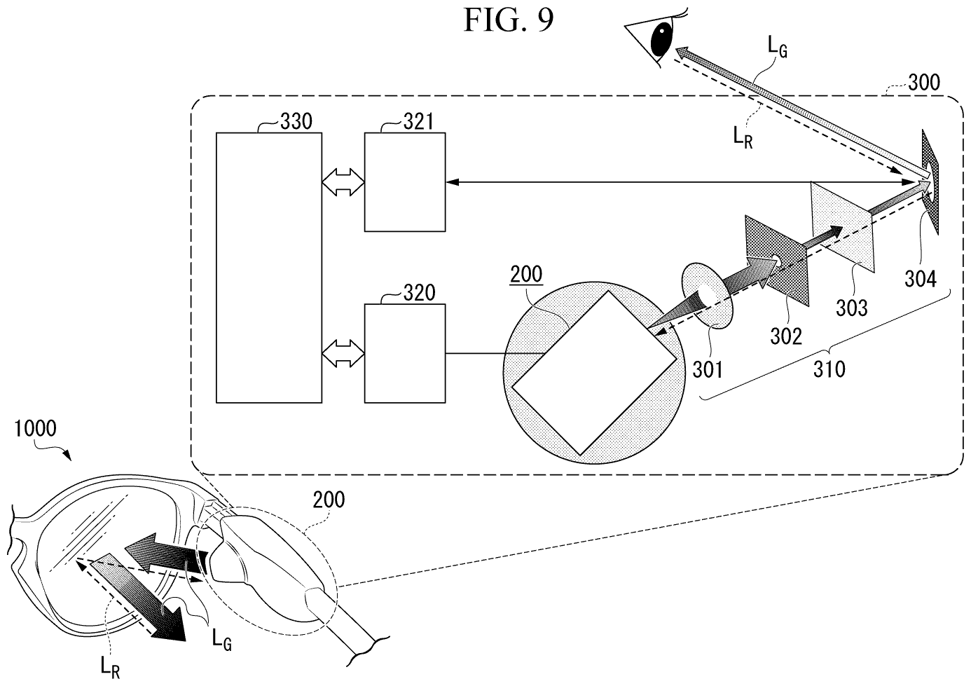

FIG. 9 is a conceptual diagram of an optical system 300 using the optical unit 200. The optical system 300 can be mounted, for example, in an eyeglass 1000.

The optical system 300 includes the optical unit 200, an optical system 310, drivers 320 and 321, and a controller 330. The optical system 310 includes, for example, a collimator lens 301, a slit 302, an ND filter 303, and an optical scanning mirror 304. The optical system 310 guides light output from the optical unit 200 to an irradiation subject (an eye in this example). The optical scanning mirror 304 is, for example, a two-axis MEMS mirror that changes a reflecting direction of laser light to a horizontal direction and a vertical direction. The optical system 310 is an example and is not limited to this example. The driver 320 controls the output from the light source 120 of the optical unit 200. The driver 321 is a control system for moving the optical scanning mirror 304. The controller 330 controls the drivers 320 and 321.

Light L_{G} output from the light source 120 of the optical unit 200 propagates in the optical system 310, is reflected by a lens of the eyeglass 1000, and is incident on an eye. In this example, light is reflected by the lens of the eyeglass 1000, but light may be directly applied to the eye.

Light L_{G} of red, green, and blue emitted from the light source 120 displays an image. The image can be freely controlled. Output intensities of the red layer 121, the green laser 122, and the blue laser 123 can be adjusted on the basis of measurement results of an output from the optical sensor 100 which is irradiated with visible light output from the red layer 121, the green laser 122, and the blue laser 123.

By using this optical system 300, it is possible to project an image onto the eyeglass 1000. By monitoring the intensity of projected light using the optical sensor 100, it is possible to adjust color tones of an image.

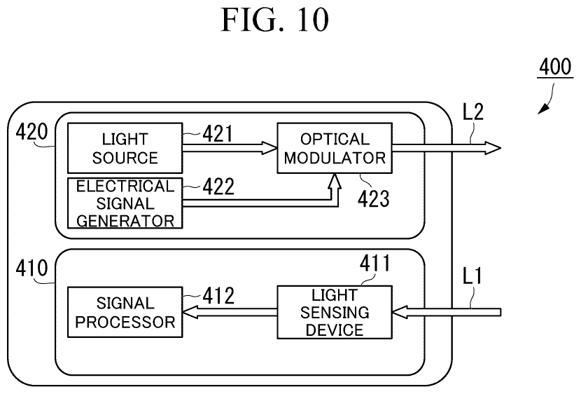

FIG. 10 is a block diagram illustrating a transceiver device 400 according to a second application example. The transceiver device 400 includes a receiver device 410 and a transmitter device 420. The receiver device 410 receives an optical signal L1, and the transmitter device 420 transmits an optical signal L2.

The receiver device 410 includes, for example, a light sensing device 411 and a signal processor 412. The aforementioned optical sensor 100 can be used as the light sensing device 411. In the receiver device 410, for example, a light pulse is applied to the optical sensor 100 of the light sensing device 411. The optical signal L1 includes a light pulse. The light sensing device 411 converts the optical signal L1 to an electrical signal. The signal processor 412 processes the electrical signal which is a conversion result from the light sensing device 411. The signal processor 412 receives a signal included in the optical signal L1 by processing the electrical signal from the light sensing device 411. The receiver device 410 receives a signal included in the optical signal L1 on the basis of an output signal from the light sensing device 411.

The transmitter device 420 includes, for example, a light source 421, an electrical signal generator 422, and an optical modulator 423. The light source 421 is, for example, a laser unit. The light source 421 may be provided outside of the transmitter device 420. The electrical signal generator 422 generates an electrical signal on the basis of transmission information. The electrical signal generator 422 may form a unified body along with a signal converter in the signal processor 412. The optical modulator 423 modulates light output from the light source 421 on the basis of the electrical signal generated by the electrical signal generator 422 and outputs the optical signal L2.

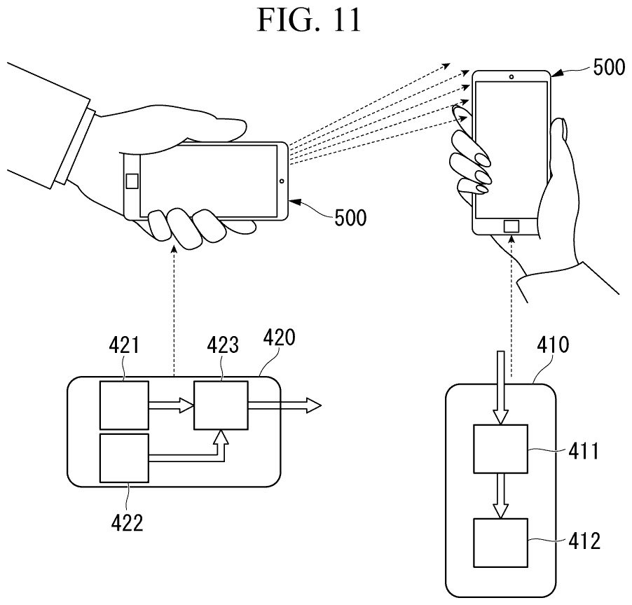

FIG. 11 is a conceptual diagram illustrating an example of a communication system. The communication system illustrated in FIG. 11 includes two terminal devices 500. The terminal devices 500 are, for example, smartphones, tablets, or personal computers.

Each terminal device 500 includes the receiver device 410 and the transmitter device 420. An optical signal transmitted from the transmitter device 420 of one terminal device 500 is received by the receiver device 410 of the other terminal device 500. Light used in transmission and reception between the terminal devices 500 is, for example, visible light. The receiver device 410 includes the light sensing device 411.

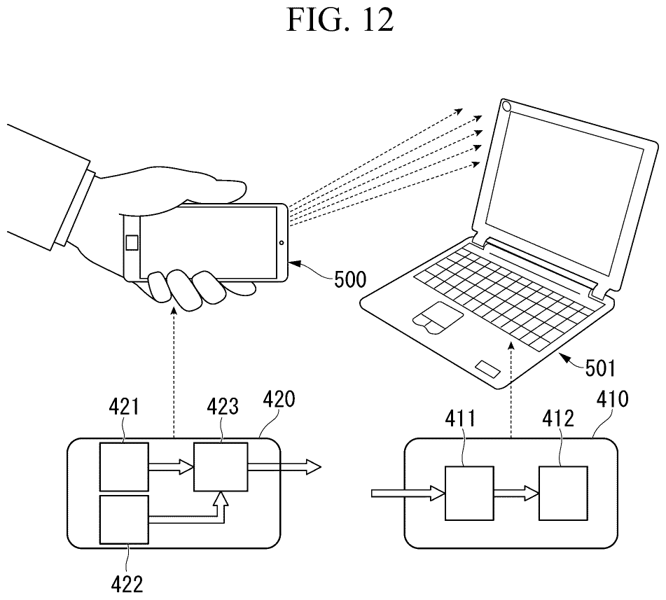

FIG. 12 is a conceptual diagram illustrating an example of a communication system. In the example illustrated in FIG. 11, both the terminal devices 500 are smartphones, but the terminal devices 500 may be different between a transmitting side and a receiving side. For example, a terminal device 500 illustrated in FIG. 12 is a smartphone, and a terminal device 501 is a personal computer.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

1 First ferromagnetic layer

2 Second ferromagnetic layer

3 Spacer layer

4 Buffer layer

5 Seed layer

6 Third ferromagnetic layer

7 Magnetic coupling layer

8 Perpendicular magnetization inducing layer

9 Cap layer

10 Photosensitive layer

21 First electrode

22 Second electrode

30 Metal layer

100, 101 Optical sensor

What is claimed is:

1. An optical sensor comprising:
a photosensitive layer that generating a voltage when the photosensitive layer is irradiated with light;
a first electrode;
a second electrode; and
a metal layer,
wherein the photosensitive layer is located between the first electrode and the second electrode,
wherein the metal layer is located between the first electrode and the photosensitive layer,
wherein the metal layer includes one selected from a group consisting of Ti, Ta, Cr, Mo, W, and Pt in a case where the photosensitive layer is irradiated with light of a wavelength equal to or greater than 400 nm and equal to or less than 800 nm,
wherein the metal layer includes one selected from a group consisting of Ti, Cr, Mo, W, and Pt in a case where the photosensitive layer is irradiated with light of a wavelength equal to or greater than 400 nm and equal to or less than 1400 nm, and
wherein the metal layer includes one selected from a group consisting of Ti, Cr, W, and Pt in a case where the photosensitive layer is irradiated with light of a wavelength equal to or greater than 400 nm and equal to or less than 1500 nm.

2. The optical sensor according to claim 1, wherein the first electrode is a transparent electrode.

3. The optical sensor according to claim 1, wherein the photosensitive layer includes a first ferromagnetic layer, a second ferromagnetic layer, and a spacer layer which is located between the first ferromagnetic layer and the second ferromagnetic layer.

4. The optical sensor according to claim 1, wherein a thermal conductivity of the metal layer is equal to or less than 60 W/mK.

5. The optical sensor according to claim 1, wherein a thickness of the metal layer is equal to or greater than 100 Å and equal to or less than 1000 Å.

6. A receiver device comprising the optical sensor according to claim 1.

7. A transceiver device comprising the receiver device according to claim 6.

8. A communication system comprising the receiver device according to claim 6.

9. A terminal device comprising the receiver device according to claim 6.

10. An optical system comprising the optical sensor according to claim 1.
